(19) United States
(12) Patent Application Publication
(10) Pub. No.: US 2025/0246873 A1
(43) Pub. Date: Jul. 31, 2025

(54) OPTOELECTRONIC MODULE AND METHOD FOR PRODUCING AN OPTOELECTRONIC MODULE

(71) Applicant: ams-OSRAM International GmbH, Regensburg (DE)

(72) Inventors: Tobias HAUPELTSHOFER, Breitenbrunn (DE); Andreas FRÖHLICH, Regensburg (DE)

(73) Assignee: ams-OSRAM International GmbH, Regensburg (DE)

(21) Appl. No.: 18/848,675

(22) PCT Filed: Mar. 22, 2023
(86) PCT No.: PCT/EP2023/057307

§ 371 Date: Sep. 19, 2024

(30) Foreign Application Priority Data
Mar. 24, 2022 (DE) 10 2022 106 943.5
Oct. 17, 2022 (DE) 10 2022 127 065.3

(51) Int. Cl. H01S 5/02315; H01L 23/498; H01S 5/0239; H01S 5/10; H01S 5/22

(52) U.S. Cl. CPC H01S 5/02315; H01L 23/49838; H01S 5/0239; H01S 5/1092; H01S 5/22

(57) ABSTRACT

The invention relates to an optoelectronic module including a first semiconductor component on an installation face of a first support, a second semiconductor component, and a third semiconductor component on an installation face of a second support. The semiconductor components are designed to emit electromagnetic radiation with different main wavelengths in a common emission direction. The installation face of the first support faces the installation face of the second support. The invention additionally relates to a method for producing an optoelectronic module.

### CROSS-REFERENCE TO RELATED APPLICATIONS

The present application is a national stage entry from International Application No. PCT/EP2023/057307, filed on Mar. 22, 2023, published as International Publication No. WO 2023/180369 A1 on Sep. 28, 2023, and claims priority to German Patent Application Nos. 10 2022 106 943.5, filed Mar. 24, 2022, and 10 2022 127 065.3, filed Oct. 17, 2022, the disclosures of all of which are hereby incorporated by reference in their entireties.

### FIELD

An optoelectronic module and a method for producing an optoelectronic module are disclosed. The optoelectronic module is configured to emit electromagnetic radiation.

### BACKGROUND

One task to be solved is to specify an optoelectronic module with a particularly compact design.

A further task to be solved is to specify a method for producing an optoelectronic module with a particularly compact design.

These tasks are solved by a device and the method according to the independent patent claims. Advantageous embodiments and further embodiments of the device and the method are the subject of the dependent patent claims and are further apparent from the following description and the figures.

### SUMMARY

According to at least one embodiment, the optoelectronic module comprises a first semiconductor component on a mounting side of a first carrier, a second semiconductor component and a third semiconductor component on a mounting side of a second carrier. The mounting side of the carriers is, for example, the side on which a semiconductor component can be mounted. In particular, the mounting side comprises in each case a plurality of solder pads for mounting semiconductor components. The first carrier and/or the second carrier are formed in particular with a plurality of layers. Preferably, the carriers are mechanically self-supporting. The semiconductor components are configured as luminescence diodes or laser diodes, for example. In particular, the semiconductor components are each designed as a single ridge laser with one emitter region each.

According to at least one embodiment of the optoelectronic module, the semiconductor components are configured to emit electromagnetic radiation of different main wavelengths in a common emission direction. In particular, the semiconductor components are designed as edge emitters, each with an emission side. In other words, the semiconductor components in particular each have an output coupling facet on one side surface. For example, the semiconductor components are each formed as monolithic components.

Here and in the following, a main wavelength describes a wavelength at which an emission spectrum has a global intensity maximum. The first semiconductor component preferably emits electromagnetic radiation with at least a first main wavelength in the red spectral range. The second semiconductor component preferably emits electromagnetic radiation with at least a second main wavelength in the green spectral range. The third semiconductor component preferably emits electromagnetic radiation with at least a third main wavelength in the blue spectral range.

Preferably, the emission directions of all semiconductor components are aligned parallel to each other. In particular, the emission direction of the semiconductor components is aligned parallel to the mounting sides of the carriers.

According to at least one embodiment of the optoelectronic module, the mounting side of the first carrier faces the mounting side of the second carrier. In particular, the mounting sides face each other in such a way that a main extension plane of the first carrier is aligned parallel to a main extension plane of the second carrier.

According to at least one embodiment, the optoelectronic module comprises:
a first semiconductor component on a mounting side of a first carrier,
a second semiconductor component and a third semiconductor component on a mounting side of a second carrier, wherein
the semiconductor components are configured to emit electromagnetic radiation of different main wavelengths in a common emission direction,
the mounting side of the first carrier faces the mounting side of the second carrier.

An optoelectronic module described here is based on the following considerations, among others: Very compact light sources are required in a variety of applications. For example, compact light sources are advantageous for projecting multicolored image content onto a portable device. Conventional light sources often take up a large installation space and emit electromagnetic radiation only slightly directed over a large area. Consequently, large and heavy optics are also required, which can further increase the dimensions of a portable light source.

The optoelectronic module described here makes use, among other things, of the idea of arranging a plurality of semiconductor components on mounting sides of different carriers and then orienting the carriers with the mounting sides facing each other. This results in a particularly compact optoelectronic module. The emission of electromagnetic radiation can be advantageously directed over a small area. Downstream optics can therefore be very small and compact. Such an arrangement of the semiconductor components also allows short control lines to be used, which facilitates high-frequency control of the semiconductor components.

According to at least one embodiment of the optoelectronic module, a frame body is arranged between the first carrier and the second carrier. In particular, the frame body is a mechanical spacer between the first carrier and the second carrier. The frame body can also protect the semiconductor components from external environmental influences.

According to at least one embodiment of the optoelectronic module, the frame body is formed with an electrically insulating material and comprises a plurality of electrical connection lines. For example, the frame body is formed with a ceramic or a polymer. The connection lines are provided in particular for supplying an operating current to a semiconductor component. For example, the connection lines are formed with a metal.

According to at least one embodiment of the optoelectronic module, the connection lines are arranged on an inner side of the frame body. Here and in the following, the inner side of the frame body is the side of the frame body facing the semiconductor components. Advantageously, the connection lines on the inner side of the frame body are particularly well protected from external environmental influences. Furthermore, the production of the connection lines on the inner side can be simplified.

According to at least one embodiment of the optoelectronic module, the connection lines are at least partially embedded in the frame body. Embedded connection lines are protected from external environmental influences. Contact between the connection lines and other components can be avoided. The risk of an electrical short circuit is advantageously reduced.

According to at least one embodiment of the optoelectronic module, a connecting material is arranged between the frame body and the first carrier and between the frame body and the second carrier in each case. In particular, the connecting material creates a hermetically sealed connection between the frame body and the first and second carriers. For example, the connecting material is formed with a solder material, in particular a gold-tin solder.

According to at least one embodiment of the optoelectronic module, the first carrier has vias through to an upper side opposite the first semiconductor component. In particular, the vias comprise a recess through the first carrier. The recesses preferably extend completely through the first carrier. The recesses of the vias are, for example, partially or completely filled with an electrically conductive material. In particular, the recesses are filled with a metal or a metal alloy. Advantageously, the vias enable electrical contacting of the first semiconductor component from the upper side of the first carrier.

According to at least one embodiment of the optoelectronic module, the upper side of the first carrier is electrically conductively connected to the first carrier via bond wires. The bond wires are formed, for example, with a metal or a metal alloy. Bond wires are advantageously easy to manufacture and can, for example, replace vias via the first carrier.

According to at least one embodiment of the optoelectronic module, at least two bond wires are assigned to each via. An increased number of bond wires per via enables improved high-frequency behavior of the electrical connection. Preferably, at least three bond wires are assigned to each via.

According to at least one embodiment of the optoelectronic module, the semiconductor components comprise a plurality of emitter regions. In particular, all semiconductor components each have a plurality of emitter regions. For example, the semiconductor components have at least two, preferably at least four and particularly preferably at least 12 emitter regions. In particular, each emitter region emits electromagnetic radiation with an identical main wavelength. Each semiconductor component can, for example, be formed as a double ridge laser with two emitter regions each. For example, the main wavelengths of the emitter regions of a semiconductor component differ by at least 1 nm, preferably by at least 2 nm, particularly preferably by at least 5 nm. Small differences in the main wavelength can advantageously reduce or avoid undesirable interference effects.

According to at least one embodiment of the optoelectronic module, the emitter regions of each semiconductor component can be controlled independently of each other. Independent control enables, for example, a particularly large dynamic range of the intensity of the emitted electromagnetic radiation.

According to at least one embodiment of the optoelectronic module, the emitter regions of all semiconductor components are arranged facing each other. In particular, all emitter regions of the optoelectronic module are arranged in an ellipse with a minor axis length of at most 200 μm, preferably of at most 100 μm and particularly preferably of at most 60 μm and a major axis length of at most 1000 μm, preferably of at most 500 μm and particularly preferably of at most 300 μm. Such a compact arrangement of the emitter regions enables the use of particularly compact downstream optical elements.

According to at least one embodiment of the optoelectronic module, a distance between the emitter regions of a semiconductor component is at most 10 μm. A small distance between the emitter regions of a semiconductor component contributes to a compact design of the optoelectronic module.

According to at least one embodiment of the optoelectronic module, a lateral distance from the second semiconductor component to the third semiconductor component is at most 30 μm, preferably at most 10 μm. A lateral distance means a distance between the second semiconductor component and the third semiconductor component in a direction parallel to the mounting side of the second carrier. A small lateral distance enables a compact design of the optoelectronic module.

According to at least one embodiment of the optoelectronic module, the first semiconductor component is vertically spaced from the second semiconductor component and the third semiconductor component by at most 50 μm, preferably at most 30 μm. A vertical distance means a distance in a direction transverse, in particular perpendicular, to the mounting side of the second carrier. The vertical distance is set in particular by a vertical expansion of the frame body and the semiconductor components.

According to at least one embodiment of the optoelectronic module, the first carrier and/or the second carrier are formed with an electrically insulating material. In particular, the first carrier and/or the second carrier are formed with one of the following materials: ceramic, silicon, glass.

According to at least one embodiment of the optoelectronic module, the second carrier comprises vias to a contact side opposite the mounting side. The vias in the second carrier correspond in particular to the vias in the first carrier. Solder mounting of the optoelectronic module from the contact side alone is made possible via the vias in the second carrier. This makes it easier to mount the optoelectronic module on a circuit board, for example.

According to at least one embodiment of the optoelectronic module, an optical element is arranged downstream of the semiconductor components in their emission direction. The optical element is in particular a collimating lens or a glass plate for protecting the semiconductor components. In particular, the optical element is permeable to the electromagnetic radiation generated in the optoelectronic module during operation.

According to at least one embodiment of the optoelectronic module, an encapsulation compound is arranged between the semiconductor components and the optical element. The encapsulation compound protects, for example, the semiconductor components on their emission sides from external environmental influences. Advantageously, a hermetically sealed frame body can be dispensed with. For example, the encapsulation compound is formed with a radiation permeable polysiloxane.

According to at least one embodiment of the optoelectronic module, a fourth semiconductor component is arranged on the first carrier. The fourth semiconductor component preferably has a plurality of fourth emitter regions. In particular, the fourth semiconductor component has identical optical properties to the second semiconductor component. Alternatively, the fourth semiconductor component can be configured to emit electromagnetic radiation in the infrared spectral range.

A method for producing an optoelectronic module is further disclosed. In particular, the optoelectronic module can be produced by means of the method described herein. That is, all features disclosed in connection with the optoelectronic module are also disclosed for the method for producing an optoelectronic module and vice versa.

According to at least one embodiment of the method, a first sub-module with a first carrier and a first frame element is provided. The first sub-module is designed, for example, as a multilayer ceramic substrate. The first frame element is preferably formed with metal.

According to at least one embodiment of the method, a first semiconductor component is mounted on the first carrier. For example, the semiconductor component is mounted on the first carrier by means of a soldering process. In particular, a mounting body is arranged between the semiconductor component and the first carrier. The mounting body is formed with ceramic, for example.

According to at least one embodiment of the method, a second sub-module is provided with a second carrier, a frame body and a second frame element. The second sub-module is designed, for example, as a multilayer ceramic substrate. In particular, the frame body comprises a plurality of layers. This can advantageously increase the vertical expansion of the frame body. The second frame element is preferably made of metal.

According to at least one embodiment of the method, a second semiconductor component and a third semiconductor component are mounted on the second carrier. For example, the second and third semiconductor components are mounted on the second carrier by means of a soldering process.

According to at least one embodiment of the method, the first sub-module is connected to the second sub-module. Preferably, the first and second sub-modules are connected by means of a soldering process. In particular, the sub-modules are connected to one another in such a way that a hermetically sealed optoelectronic module is formed.

According to at least one embodiment of the method, the method comprises the following steps:
providing a first sub-module with a first carrier and a first frame element,
mounting a first semiconductor component on the first carrier,
providing a second sub-module with a second carrier, a frame body and a second frame element,
mounting a second semiconductor component and a third semiconductor component to the second carrier, and
connecting the first sub-module to the second sub-module.

According to at least one embodiment of the method, a plurality of connection lines are introduced into the frame body. For example, the frame body is formed with a ceramic or a polymer. The connection lines are provided in particular for supplying an operating current to a semiconductor component. For example, the connection lines are formed with a metal. The connection lines are preferably embedded in the frame body. Embedded connection lines are protected from external environmental influences. Contact between the connection lines and other components can be avoided. The risk of an electrical short circuit is advantageously reduced.

According to at least one embodiment of the method, the first frame element is applied to the second frame element between the first sub-module and the second sub-module. In particular, the first frame element and the second frame element are in direct contact with each other. Preferably, a lateral expansion and shape of the first frame element are identical to a lateral expansion and shape of the second frame element. The first frame element and the second frame element can each form a closed shape.

According to at least one embodiment of the method, the first semiconductor component is mounted on the cathode side and the anode side of the first carrier. In other words, a cathode and an anode of the first semiconductor component are oriented facing the first carrier. The first semiconductor component is thus preferably mounted “p-up”, which means that electrical contacting of the first semiconductor component can advantageously be made from a single side of the first semiconductor component. Bond wires can advantageously be dispensed with.

According to at least one embodiment of the method, the second semiconductor component and the third semiconductor component are each mounted on the cathode side of the second carrier. In other words, a cathode of the second semiconductor component and a cathode of the third semiconductor component are each oriented facing the second carrier. The second and third semiconductor components are therefore preferably mounted “p-up”. In particular, the anodes of the second and third semiconductor components are arranged on a side facing away from the second carrier. An anode of the second semiconductor component and an anode of the third semiconductor component can, for example, each be electrically contacted with bond wires.

An optoelectronic module described here is particularly suitable for use as a compact laser light source in portable projection applications, head-up displays, augmented displays or virtual reality displays.

Further advantages and advantageous configurations and further embodiments of the optoelectronic module result from the following exemplary embodiments shown in connection with the figures.

### BRIEF DESCRIPTION OF THE DRAWINGS

FIGS. 1A, 1B and 1C schematic sectional views and a top view of an optoelectronic module described herein according to a first exemplary embodiment from different viewing directions,

FIG. 2 a schematic sectional view of an optoelectronic module described here according to a second exemplary embodiment,

FIGS. 3A and 3B schematic sectional views of an optoelectronic module described herein according to a third exemplary embodiment from different viewing directions,

FIGS. 4A and 4B schematic sectional views of an optoelectronic module described herein according to a fourth exemplary embodiment from different viewing directions,

FIGS. 5A and 5B schematic sectional views of an optoelectronic module described herein according to a fifth exemplary embodiment from different viewing directions,

FIG. 6 a schematic sectional view of an optoelectronic module described here according to a sixth exemplary embodiment,

FIGS. 7A to 10B schematic sectional views and schematic plan views of a first sub-module of an optoelectronic module described herein in various steps of a method for its manufacture,

FIGS. 11A to 17B schematic sectional views and schematic plan views of a second sub-module of an optoelectronic module described herein in various steps of a method for its manufacture, and

FIGS. 18A and 18B schematic sectional views of an optoelectronic module described herein according to a seventh embodiment.

### DETAILED DESCRIPTION

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

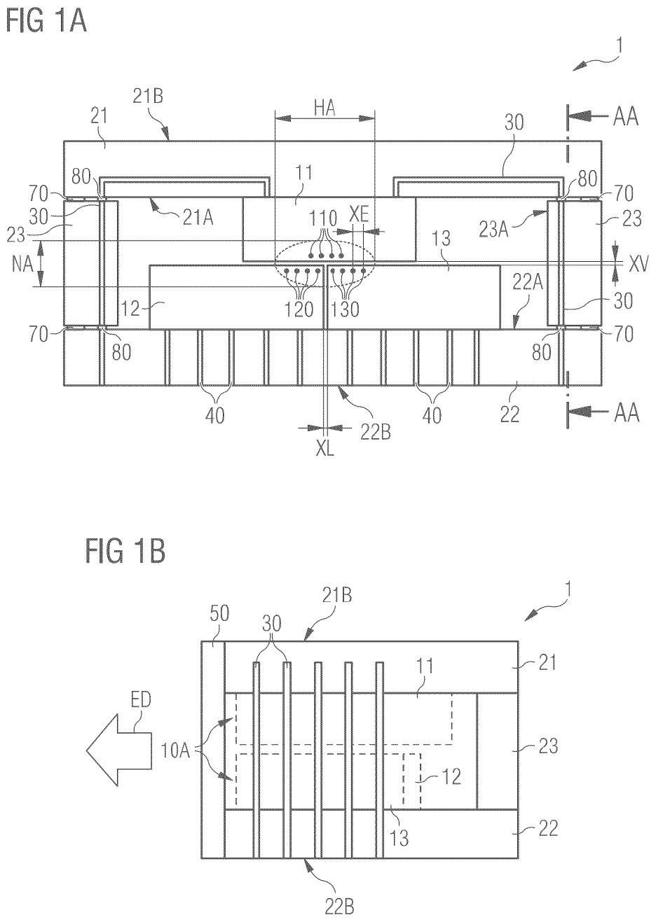

FIG. 1A shows a schematic sectional view of an optoelectronic module 1 described herein according to a first exemplary embodiment. The optoelectronic module 1 comprises a first semiconductor component 11 on a mounting side 21A of a first carrier 21, a second semiconductor component 12 and a third semiconductor component 13 on a mounting side 22A of a second carrier 22. The mounting side 21A, 22A of the carriers 21, 22 is in each case the side on which a semiconductor component 11, 12, 13 can be mounted. In particular, the mounting sides 21A, 22A each comprise a plurality of solder pads for mounting semiconductor components 11, 12, 13.

The first carrier 21 and/or the second carrier 22 are multilayered. The first carrier 21 and the second carrier 22 are mechanically self-supporting. The first carrier 21 and the second carrier 22 are formed with an electrically insulating material. In particular, the first carrier 21 and the second carrier 22 are formed with one of the following materials: ceramic, silicon, glass. Furthermore, the first carrier 21 comprises connection lines 30, which are provided for the electrical connection of the first semiconductor component 11. The connection lines 30 are at least partially or preferably completely embedded in the first carrier 21.

The second carrier 22 comprises vias 40 to a contact side 22B opposite the mounting side 22A. The vias 40 extend to a contact side 22B opposite the second semiconductor component 12 and the third semiconductor component 13. In particular, the vias 40 each comprise a recess through the second carrier 22. The recesses extend completely through the second carrier 22. For example, the recesses of the vias 40 are partially or completely filled with an electrically conductive material. In particular, the recesses are filled with a metal or a metal alloy. Advantageously, the vias 40 enable electrical contacting of the second and third semiconductor components 12, 13 from the contact side 22B of the second carrier 22. Consequently, solder mounting of the optoelectronic module 1 from the contact side 22B alone is made possible by means of the vias 40 in the second carrier 22. Mounting of the optoelectronic module 1 on a circuit board, for example, can thus be simplified.

The semiconductor components 11, 12, 13 are formed, for example, as luminescence diodes or laser diodes. The semiconductor components 11, 12, 13 are configured to emit electromagnetic radiation of different main wavelengths in a common emission direction ED. In particular, the semiconductor components 11, 12, 13 are formed as edge emitters each having an emission side. In other words, the semiconductor components 11, 12, 13 in particular each have an output coupling facet 10A on one side surface.

The first semiconductor component 11 emits electromagnetic radiation with at least a first main wavelength in the red spectral range. The second semiconductor component 12 emits electromagnetic radiation with at least a second main wavelength in the green spectral range. The third semiconductor component 13 emits electromagnetic radiation with at least a third main wavelength in the blue spectral range. The emission directions ED of all semiconductor components 11, 12, 13 are aligned parallel to each other. The emission direction ED of the semiconductor components 11, 12, 13 is aligned parallel to the mounting sides 21A, 22A of the carriers 21, 22.

The semiconductor components 11, 12, 13 each have a plurality of emitter regions 110, 120, 130. For example, an emitter region 110, 120, 130 corresponds to a ridge on a semiconductor component 11, 12, 13. The semiconductor components 11, 12, 13 each have four emitter regions 110, 120, 130. In particular, each emitter region 110, 120, 130 emits electromagnetic radiation with an identical main wavelength. For example, the main wavelengths of the emitter regions 110, 120, 130 of a semiconductor component 11, 12, 13 differ from each other by at least 1 nm, preferably by at least 2 nm, particularly preferably by at least 5 nm. Small differences in the main wavelength can advantageously reduce or avoid undesirable interference effects. The emitter regions 110, 120, 130 of each semiconductor component 11, 12, 13 can be controlled independently of each other. Independent control enables, for example, a particularly wide dynamic range of the intensity of the emitted electromagnetic radiation.

The emitter regions 110, 120, 130 of all semiconductor components 11, 12, 13 are arranged facing each other. This advantageously results in the smallest possible distance between the emitter regions 110, 120, 130. In particular, all emitter regions 110, 120, 130 of the optoelectronic module 1 are arranged in an ellipse with a minor axis length NA of at most 60 μm and a major axis length HA of at most 300 μm. Such a compact arrangement of the emitter regions 110, 120, 130 enables the use of particularly compact downstream optical elements 50.

A frame body 23 is arranged between the first carrier 21 and the second carrier 22. The frame body 23 is a mechanical spacer between the first carrier 21 and the second carrier 22. The frame body 23 can further protect the semiconductor components 11, 12, 13 from external environmental influences. The frame body 23 is formed with an electrically insulating material and comprises a plurality of electrical connection lines 30. For example, the frame body 23 is formed with a ceramic or a polymer. The connection lines 30 are provided in particular for supplying the first semiconductor component 11 with an operating current. The connection lines 30 are formed with a metal. The connection lines 30 are completely embedded in the frame body 30. Embedded connection lines 30 are particularly well protected from external environmental influences. Contact of the connection lines 30 with other components can thus be advantageously avoided. This reduces the risk of an electrical short circuit.

A connecting material 70 is arranged between the frame body 23 and the first carrier 21 and between the frame body 23 and the second carrier 22. The connecting material 70 effects a hermetically sealed connection between the frame body 23 and the first carrier 21 and between the frame body 23 and the second carrier 22. For example, the connecting material 70 is formed with a solder material, in particular a gold-tin solder. Furthermore, a solder material 80 is arranged between the frame body 23 and the first carrier 21 and between the frame body 23 and the second carrier 22, respectively. The solder material connects the connection line 30 in the frame body electrically conducting with the first frame body 21 and the second frame body 22.

A distance between the emitter regions 110, 120, 130 of a semiconductor component 11, 12, 13 is at most 10 μm. A small distance XE between the emitter regions 110, 120, 130 of a semiconductor component 11, 12, 13 contributes to a compact design of the optoelectronic module 1.

A lateral distance XL from the second semiconductor component 12 to the third semiconductor component 13 is at most 30 μm, preferably at most 10 μm. A lateral distance XL means a distance between the second semiconductor component 12 and the third semiconductor component 13 in a direction parallel to the mounting side 22A of the second carrier 22. A small lateral distance XL enables a compact design of the optoelectronic module 1.

The first semiconductor component 11 is vertically spaced from the second semiconductor component 12 and the third semiconductor component 13 by at most 50 μm, preferably at most 30 μm. A vertical distance XV means a distance in a direction transverse, in particular perpendicular, to the mounting side 22A of the second carrier 22. The vertical distance XV is determined in particular by a vertical expansion of the frame body 23 and the semiconductor components 11, 12, 13.

FIG. 1B shows a schematic sectional view of the optoelectronic module 1 described here according to the first exemplary embodiment along a sectional line AA of FIG. 1A. In the sectional view of FIG. 1B, it can be seen that an optical element 50 is arranged downstream of the semiconductor components 11, 12, 13 in their emission direction ED. The optical element 50 is a glass plate for protecting the semiconductor components 11, 12, 13. The optical element 50 is not in direct contact with the semiconductor components 11, 12, 13. The optical element 50 is arranged on the first carrier 21, the second carrier 22 and the frame body 23. In particular, the optical element 50 is arranged on the carriers 21, 22 and the frame body 23 by means of soldering. Preferably, the optical element is attached using a gold-tin solder. The frame body 23 has a closed rear side opposite the optical element 50 in order to hermetically enclose the semiconductor components 11, 12, 13.

FIG. 1C shows a schematic top view of the optoelectronic module 1 described here according to the first exemplary embodiment. In the top view, the U-shaped expansion of the frame body is recognizable. The semiconductor components 11, 12, 13 are thus located in a hermetically sealed space and are optimally protected from harmful environmental influences.

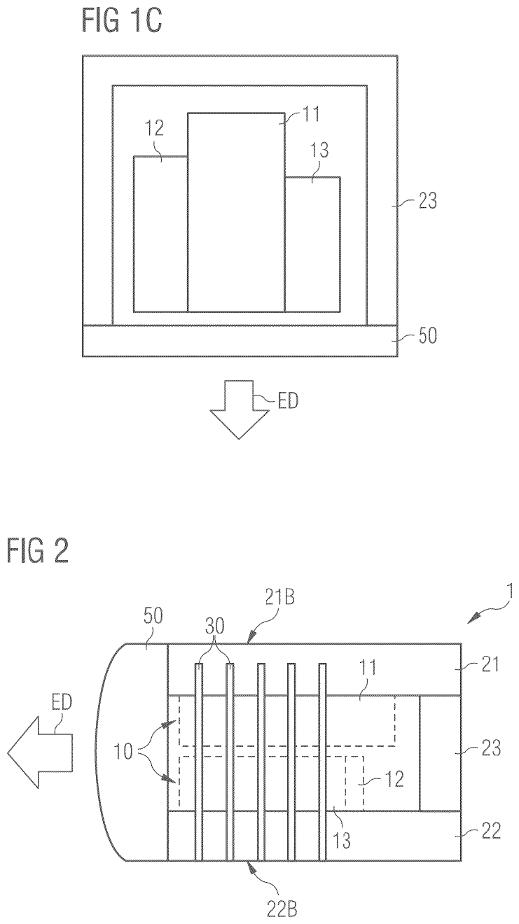

FIG. 2 shows a schematic sectional view of an optoelectronic module 1 described here according to a second exemplary embodiment. The second exemplary embodiment essentially corresponds to the first exemplary embodiment shown in FIGS. 1A, 1B and 1C. In contrast to the first exemplary embodiment, the optical element 50 is formed as a collimating lens. By means of the optical element 50, a collimation of the electromagnetic radiation of the semiconductor components 11, 12, 13 emitted in the emission direction ED can thus take place.

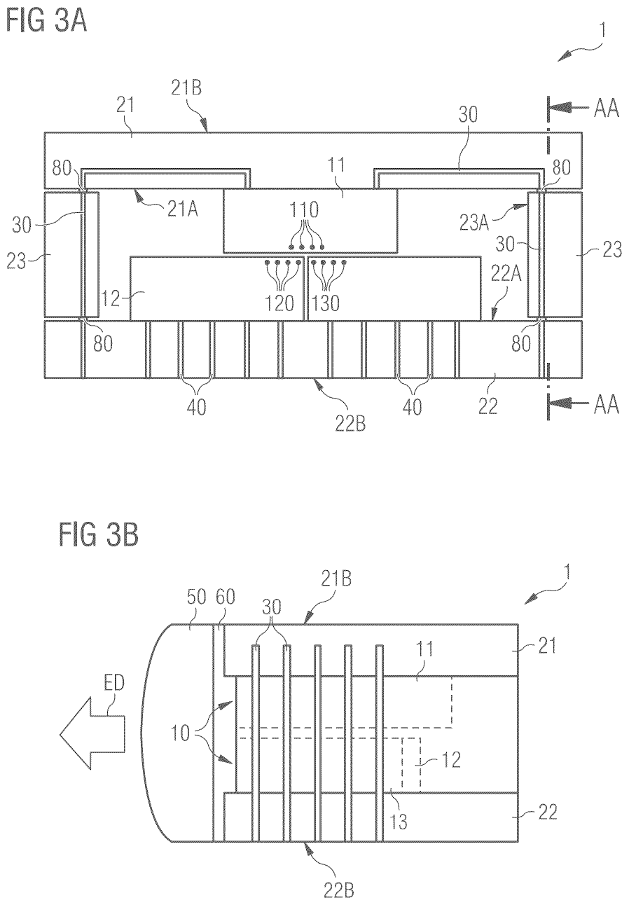

FIG. 3A shows a schematic sectional view of an optoelectronic module described herein according to a third exemplary embodiment. The third exemplary embodiment essentially corresponds to the first exemplary embodiment shown in FIG. 1A. In contrast to the first exemplary embodiment, the optoelectronic module 1 according to the third exemplary embodiment does not comprise a connecting material 70 between the frame body and the first and second carriers 21, 22. Furthermore, an encapsulation compound 60 is arranged between the output coupling facets 10A of the semiconductor components 11, 12, 13 and the optical element 50. The encapsulation compound 60 is permeable to the electromagnetic radiation generated in the optoelectronic module 1 during operation. For example, the encapsulation compound 60 is formed with a polysiloxane.

FIG. 3B shows a schematic sectional view of the optoelectronic module 1 described here according to the third exemplary embodiment along a sectional line AA of FIG. 3A. In the sectional view of FIG. 3B, the encapsulation compound 60 is shown. The output coupling facets 10A of the semiconductor components 11, 12, 13 are completely covered by the encapsulation compound 60. The semiconductor components 11, 12, 13 are thus already sufficiently protected from external environmental influences. The connecting material 70 between the frame body 23 and the first and second carriers 21, 22 can thus be dispensed with. For example, it is sufficient to connect the frame body 23 to the first and second carriers 21, 22 via the solder material 80 required for the electrical connection. Furthermore, the frame body 23 can comprise a recess on its side opposite the optical element 50. This guarantees increased design freedom.

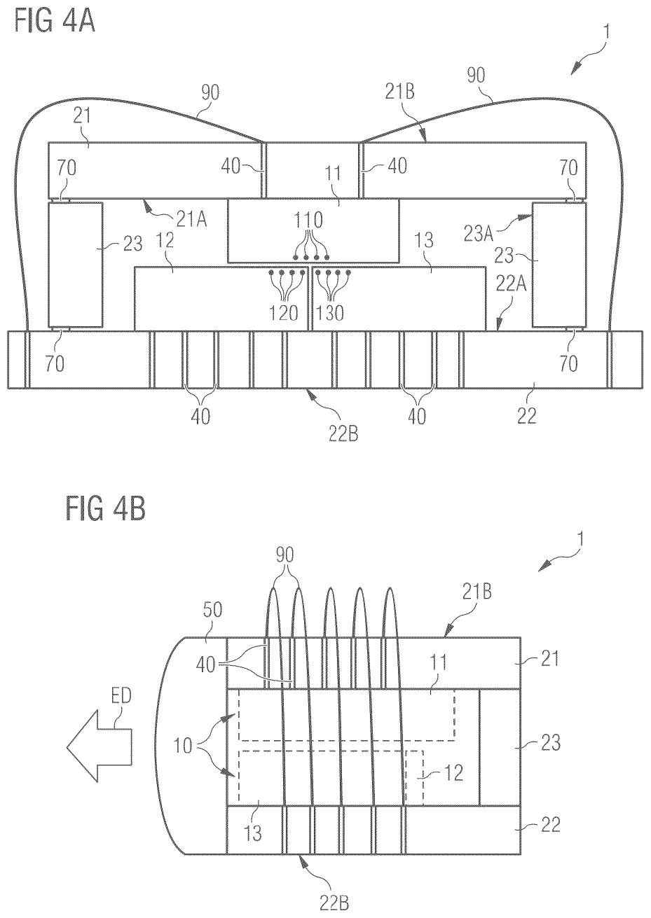

FIG. 4A shows a schematic sectional view of an optoelectronic module 1 described herein according to a fourth exemplary embodiment. The fourth exemplary embodiment essentially corresponds to the first exemplary embodiment shown in FIG. 1A. In contrast to the first exemplary embodiment, the first carrier 21 comprises vias 40, which replace the connection lines 30 in the frame body 23 and the solder material 80, and a plurality of bond wires 90 connect the first carrier 21 to the second carrier 22.

The vias 40 extend to an upper side 21B opposite the first semiconductor component 11. In particular, the vias 40 comprise a recess through the first carrier 21. The recesses extend completely through the first carrier 21. The recesses of the vias 40 are, for example, partially or completely filled with an electrically conductive material. In particular, the recesses are filled with a metal or a metal alloy. Advantageously, the vias 40 enable electrical contacting of the first semiconductor component 11 from the upper side 21A of the first carrier 21. The bond wires 90 connect vias 40 of the second carrier 22 with vias 40 on the first carrier 21. In particular, at least two bond wires 90 are assigned to each via 40. In this way, electrical resistance can be reduced and improved response behavior can be achieved at high-frequency control.

The frame body 23 can therefore be formed without electrical connection lines 30. This advantageously simplifies the manufacture of the frame body 23. Furthermore, the solder material 80 between the frame body 23 and the first and second carriers 21, 22 can be dispensed with.

FIG. 4B shows a schematic sectional view of the optoelectronic module 1 described here according to the fourth exemplary embodiment from a section transverse to FIG. 4A. In the exemplary embodiment of FIG. 4B, each via 40 on the first carrier 21 and each via 40 on the second carrier 22 are each assigned a bond wire 90. Advantageously, two or more bond wires 90 can also be assigned to each via 40.

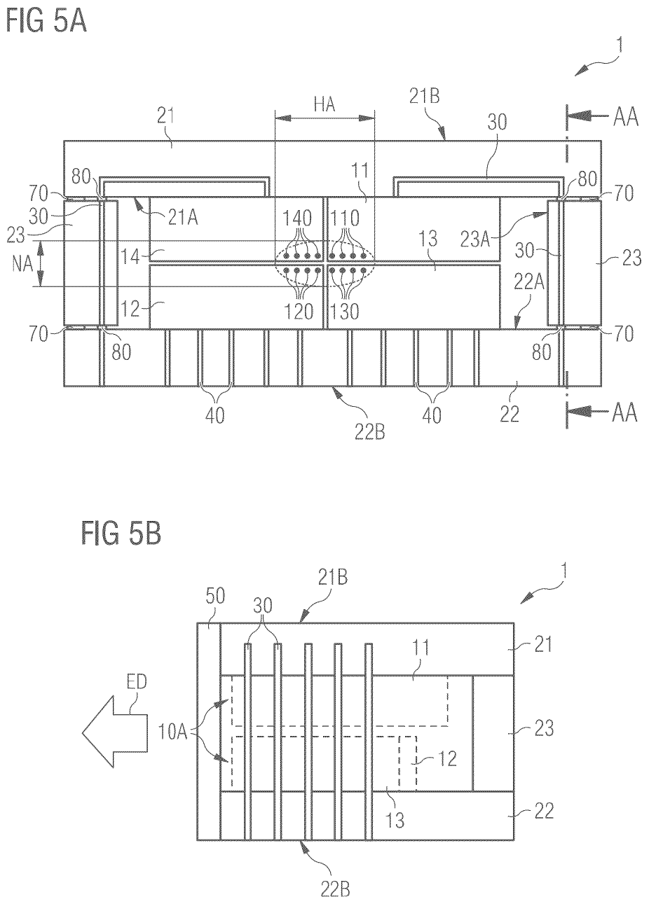

FIG. 5A shows a schematic sectional view of an optoelectronic module 1 described herein according to a fifth exemplary embodiment. The fifth exemplary embodiment essentially corresponds to the first exemplary embodiment shown in FIG. 1A. In contrast to the first exemplary embodiment, the optoelectronic module 1 comprises a fourth semiconductor component 14. The fourth semiconductor component 14 is arranged on the mounting side 21A of the first carrier 21 adjacent to the first semiconductor component 11. The fourth semiconductor component 14 comprises a plurality of fourth emitter regions 140, which are configured to emit electromagnetic radiation having at least a fourth main wavelength in a fourth spectral range. In particular, the fourth semiconductor component 14 has identical optical properties as the second semiconductor component 12. For example, the fourth semiconductor component 14 has identical main wavelengths, an identical laser threshold, identical operating currents and voltages at an operating point and an identical transconductance as the second semiconductor component 12. Alternatively, the fourth semiconductor component 14 can be configured to emit electromagnetic radiation in the infrared spectral range.

The lateral distance XL between the first semiconductor component 11 and the fourth semiconductor component 14 is at most 30 μm, preferably at most 10 μm. Preferably, the lateral distance XL between the first semiconductor component 11 and the fourth semiconductor component 14 is identical to the lateral distance XL between the second semiconductor component 12 and the third semiconductor component 13. A distance between the emitter regions 140 of the fourth semiconductor component 14 is at most 10 μm. Alternatively, electrical contacting of the fourth semiconductor component 14 by means of bond wires 90, as shown in the fourth exemplary embodiment, would also be conceivable.

FIG. 5B shows a schematic sectional view of the optoelectronic module 1 described here according to the fifth exemplary embodiment along a sectional line AA of FIG. 5A.

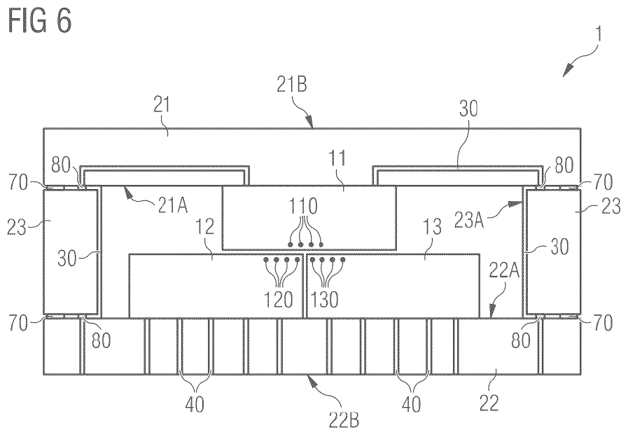

FIG. 6 shows a schematic sectional view of an optoelectronic module 1 described here according to a sixth exemplary embodiment. The sixth exemplary embodiment essentially corresponds to the first exemplary embodiment shown in FIG. 1A. In contrast to the first exemplary embodiment, the connection lines 30 are not embedded in the frame body 23 but are arranged on an inner side 23A of the frame body 23. The inner side 23A of the frame body 23 is the side of the frame body 23 facing the semiconductor components 11, 12, 13. Advantageously, the connection lines 30 on the inner side 23A of the frame body 23 are particularly well protected from external environmental influences. Furthermore, production of the connection lines 30 on the inner side 23A can be simplified compared to embedding the connection lines 30 in the frame body 23. Preferably, the connection lines 30 are applied to the inner side 23A of the frame body 23 by means of sputtering.

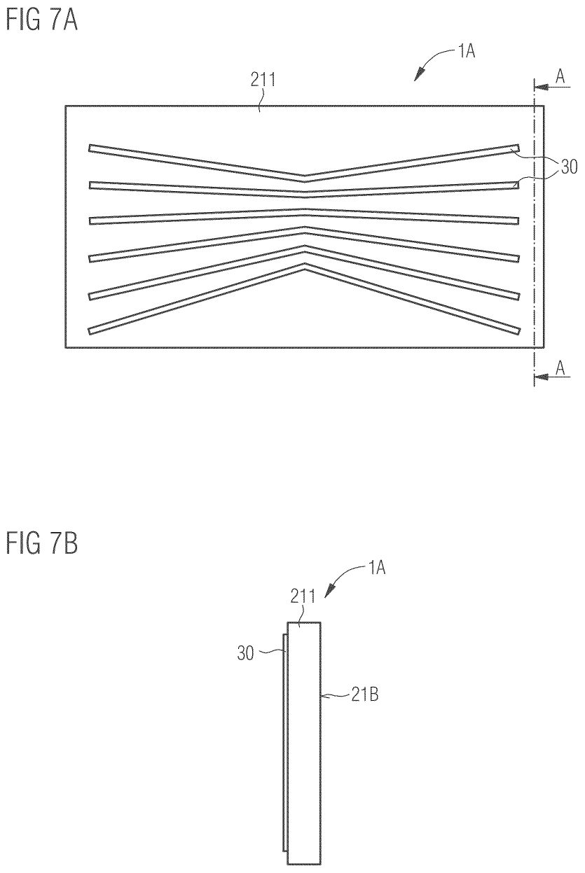

FIGS. 7A to 10B show schematic sectional views and schematic plan views of a first sub-module 1A of an optoelectronic module 1 described herein in various steps of a method for its manufacture.

FIG. 7A shows a schematic top view of a first sub-module 1A of an optoelectronic module 1 described herein. A first layer 211 of a first carrier 21 having a plurality of connection lines 30 is provided. The connection lines 30 are formed with a metal. For example, the connection lines 30 are formed with copper.

FIG. 7B shows a schematic sectional view through the component according to FIG. 7A along the sectional line AA. The first carrier 21 has an upper side 21B. The connection lines 30 are arranged on a side of the first layer 211 of the first carrier 21 opposite the upper side 21B.

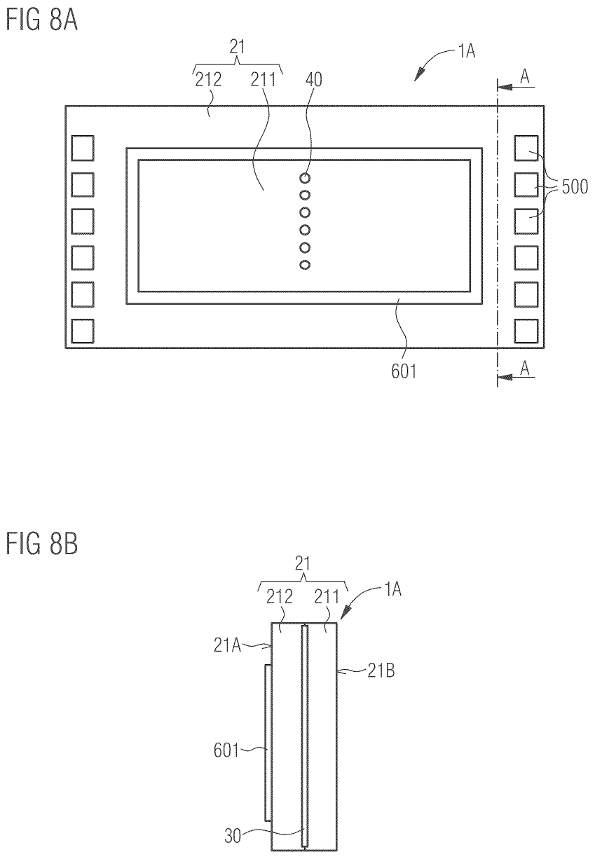

FIG. 8A shows a schematic top view of a first sub-module 1A of an optoelectronic module 1 described herein in a further step of a method for producing a first sub-module 1A. A second layer 212 of the first carrier 21 is applied to the first layer 211 of the first carrier 21. The second layer 212 of the first carrier 21 is arranged on the side opposite to the upper side 21B of the first layer 211 of the first carrier 21. The first layer 211 and the second layer 212 together form the first carrier 21. Preferably, the first layer 211 and the second layer 212 are formed with the same material. The first layer 211 and the second layer 212 of the first carrier 21 at least partially enclose the connection lines 30. A plurality of contact areas 500 are arranged on a mounting side 21A of the first carrier 21 opposite the upper side 21B. Furthermore, vias 40 extend completely through the second layer 212 of the first carrier 21.

FIG. 8B shows a schematic sectional view through the component according to FIG. 8A along the sectional line AA. In FIG. 8B, it can be seen that the connection lines 30 are at least partially embedded in the first carrier 21.

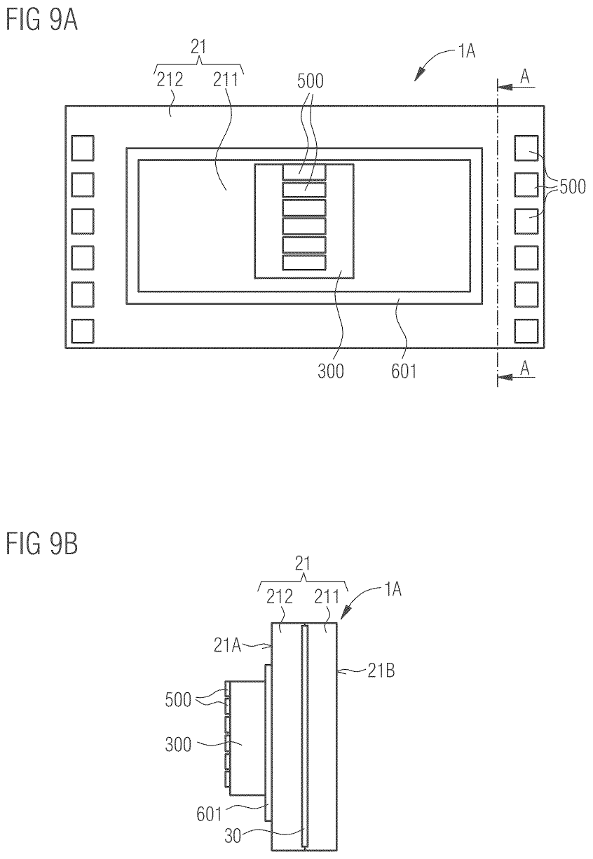

FIG. 9A shows a schematic top view of a first sub-module 1A of an optoelectronic module 1 described herein in a further step of a method for producing a first sub-module 1A. A first frame element 601 and a mounting body 300 are applied to the mounting side 21A of the first carrier 21. The first frame element 601 is formed with metal. The mounting body 300 is formed with a ceramic. The first frame element 601 completely surrounds the mounting body 300. Contact areas 500 are arranged on a side of the mounting body 300 facing away from the first carrier 21.

FIG. 9B shows a schematic sectional view of the component shown in FIG. 9A along sectional line AA.

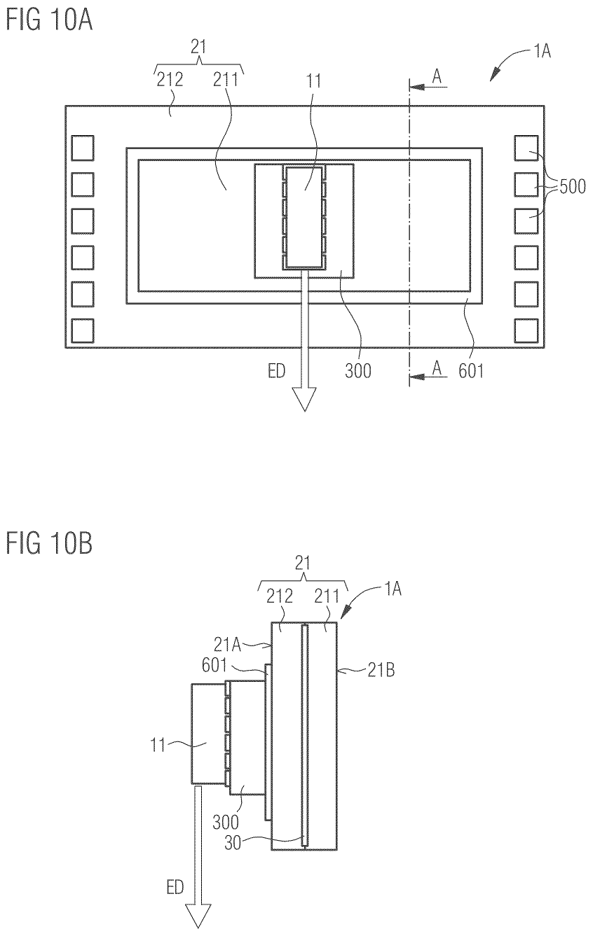

FIG. 10A shows a schematic top view of a first sub-module 1A of an optoelectronic module 1 described herein in a further step of a method for producing a first sub-module 1A. A first semiconductor component 11 is arranged on the side of the mounting body 300 facing away from the first carrier 21. The first semiconductor component 11 has its electrical contacts on a single rear side. Both the anode and the cathode of the first semiconductor component 11 are in contact with the contact areas 500 of the mounting body 300. Consequently, the first semiconductor component 11 is contacted on the anode side and the cathode side on the first carrier 21.

FIG. 10B shows a schematic sectional view through the component according to FIG. 10A along the sectional line AA. In the sectional view, it can be seen that an emission direction ED of the first semiconductor component 11 is oriented parallel to a main extension plane of the first carrier 21.

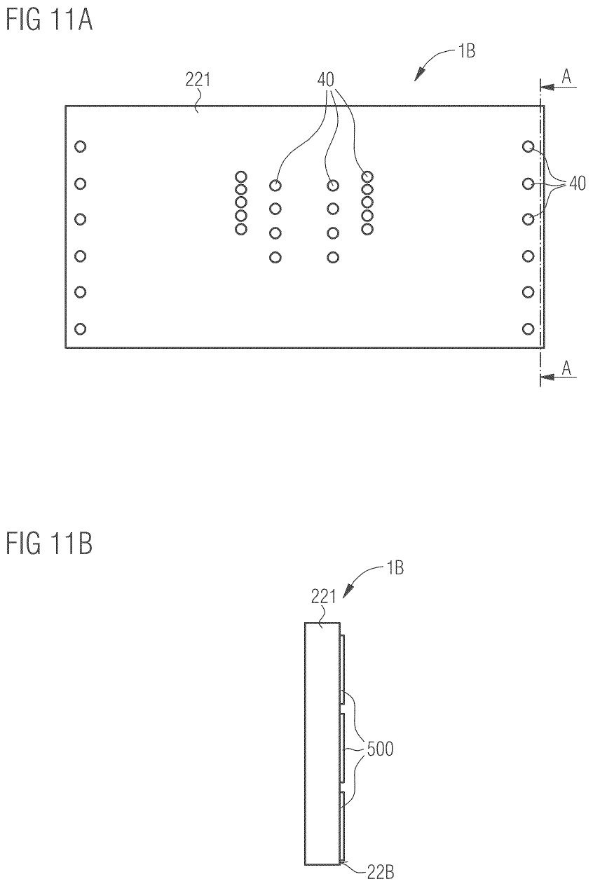

FIGS. 11A to 17B show schematic sectional views and schematic plan views of a second sub-module 1B of an optoelectronic module 1 described herein in various steps of a method for its manufacture.

FIG. 11A shows a schematic top view of a second sub-module 1B of an optoelectronic module 1 described herein. A first layer 221 of a second carrier 22 is provided. The first layer 221 of the second carrier 22 comprises a plurality of vias 40, the vias 40 extending transversely to the main extension plane of the first layer 221 of the second carrier 22 and completely through the first layer 221 of the second carrier 22.

FIG. 11B shows a schematic sectional view through the component according to FIG. 11A along the sectional line AA. A plurality of contact areas 500 is arranged on a contact side 22B of the second carrier 22.

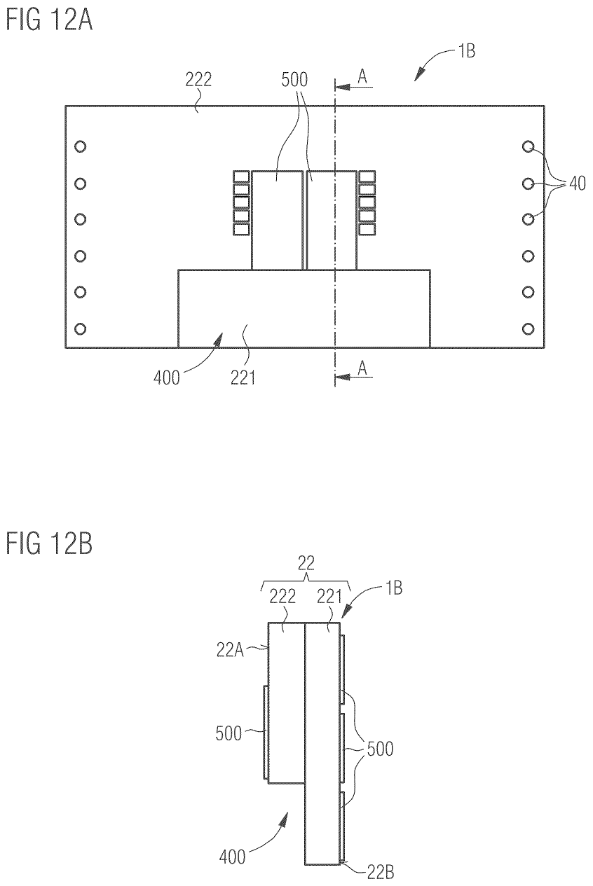

FIG. 12A shows a schematic top view of a second sub-module 1B of an optoelectronic module 1 described herein in a further step of a method for producing a second sub-module 1B. A second layer 222 of the second carrier 22 is arranged on the side opposite the contact side 22B of the first layer 221 of the second carrier 22. A plurality of contact areas 500 are arranged on the mounting side 22A of the second carrier 22 opposite the contact side 22B. Preferably, the first layer 221 of the second carrier and the second layer 222 of the second carrier are formed with the same material.

FIG. 12B shows a schematic sectional view through the component according to FIG. 12A along the sectional line AA. In the sectional view, it is clearly recognizable that the second layer 222 of the second carrier 22 has a cavity 400. The cavity 400 can advantageously reduce or avoid shadowing of the electromagnetic radiation emitted by a semiconductor component 12, 13 during operation. The cavity extends in a lateral direction starting from a contact area 500 on the second layer 222 of the second carrier 22 to the edge of the second layer 222 of the second carrier. Further, the cavity 400 completely penetrates the second layer 222 of the second carrier 22.

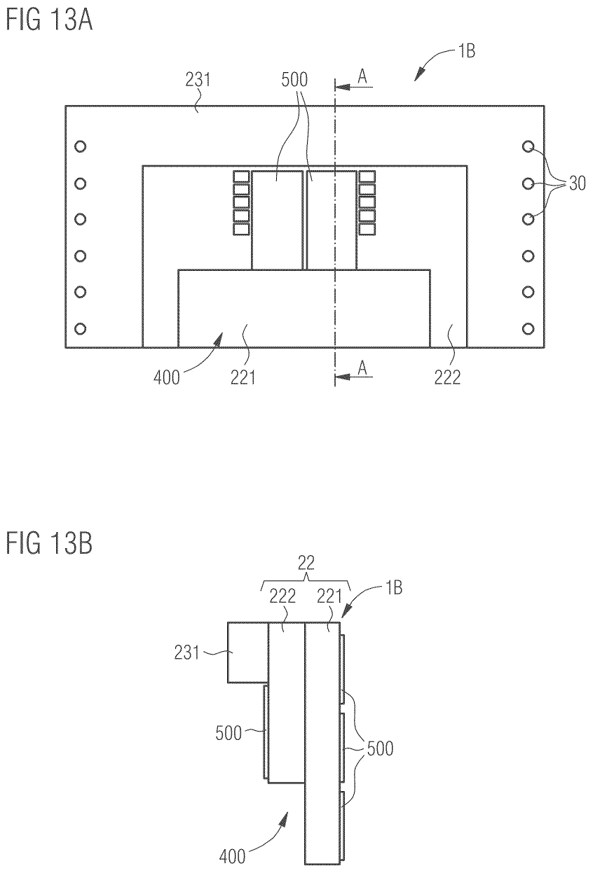

FIG. 13A shows a schematic top view of a second sub-module 1B of an optoelectronic module 1 described herein in a further step of a method for producing a second sub-module 1B. A first layer 231 of a frame body 23 is arranged on the mounting side 22A of the second carrier 22. The first layer 231 of the frame body 23 has a U-shaped lateral expansion. The cavity 400 is not covered by the frame body 23.

FIG. 13B shows a schematic sectional view through the component according to FIG. 13A along the sectional line AA.

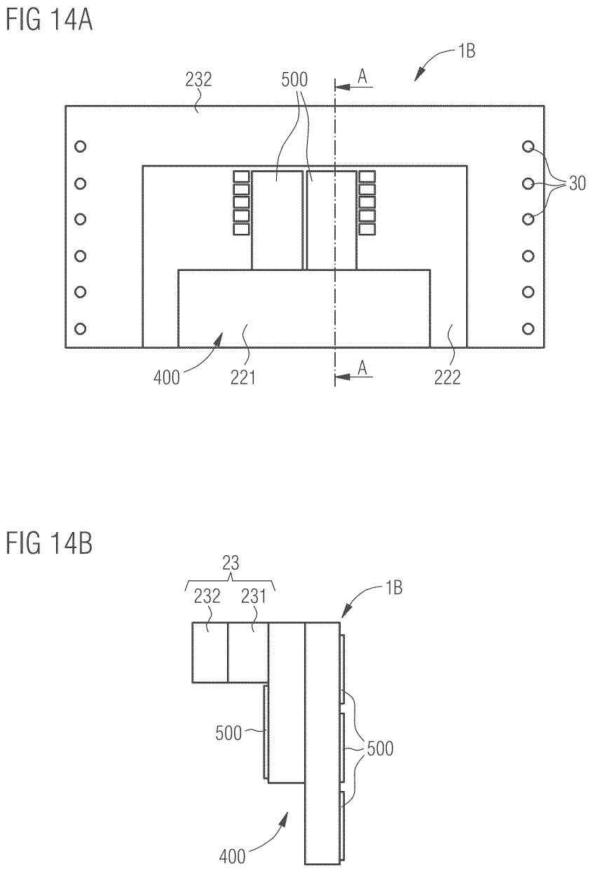

FIG. 14A shows a schematic top view of a second sub-module 1B of an optoelectronic module 1 described herein in a further step of a method for producing a second sub-module 1B. A second layer 232 of the frame body 23 is arranged on a side of the first layer 231 of the frame body 23 facing away from the mounting side 22A. The second layer 232 of the frame body 23 has a U-shaped lateral expansion. Alternatively, the first layer 231 of the frame body 23 and the second layer 232 of the frame body 23 can also be arranged in a contiguous layer in a common process step.

FIG. 14B shows a schematic sectional view through the component according to FIG. 14A along the sectional line AA.

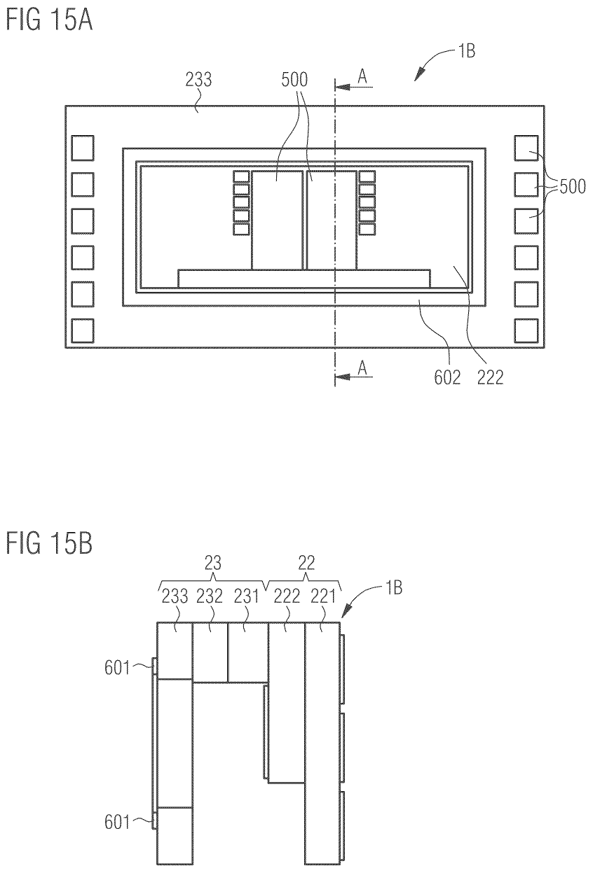

FIG. 15A shows a schematic top view of a second sub-module 1B of an optoelectronic module 1 described herein in a further step of a method for producing a second sub-module 1B. A third layer 233 of the frame body 23 is arranged on a side of the second layer 232 of the frame body 23 facing away from the mounting side 22A. The third layer 233 of the frame body 23 has an opening. A second frame element 602 extends around the opening on a side of the third layer 233 of the frame body 23 facing away from the mounting side 22A. The second frame element 602 is formed with metal. The second frame element 602 has a completely closed shape. Further, a plurality of contact areas 500 are arranged on the side of the third layer 233 of the frame body 23 facing away from the mounting side 22A. Preferably, the first layer 231, the second layer 232 and the third layer 233 of the frame body 23 are formed with the same material. The first, second and third layers 231, 232, 233 of the frame body 23 each have a thickness of between 100 μm and 300 μm. In particular, the first layer 231 and the second layer 232 of the frame body 23 each have a thickness of 100 μm and the third layer 233 of the frame body 23 in particular has a thickness of 200 μm. The frame body 23 as a whole has a thickness of at least 400 μm.

FIG. 15B shows a schematic sectional view through the component according to FIG. 15A along the sectional line AA.

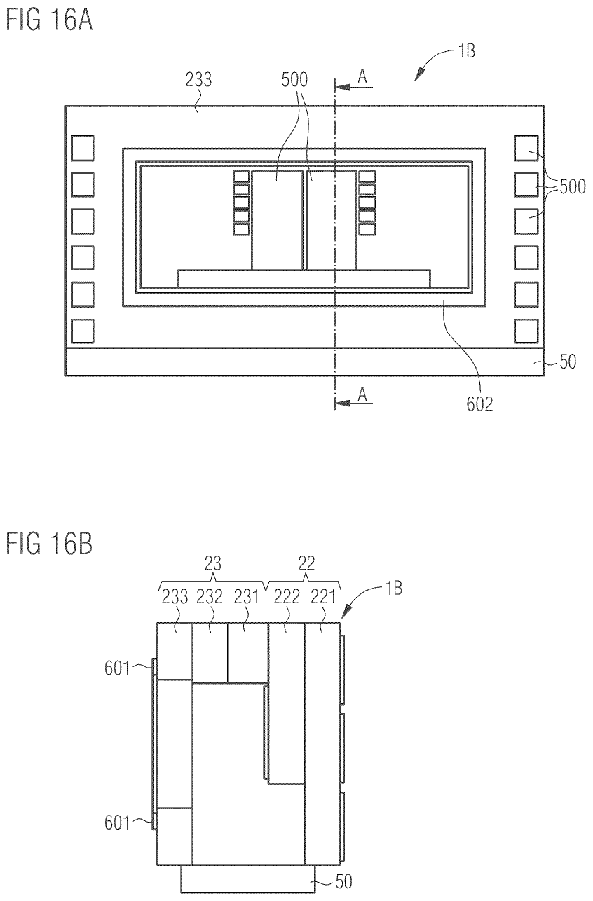

FIG. 16A shows a schematic top view of a second sub-module 1B of an optoelectronic module 1 described here in a further step of a method for producing a second sub-module 1B. An optical element 50 is arranged on the side facing the cavity 400. The only remaining opening in the second sub-module 1B is the opening in the third layer 233 of the frame body 23.

FIG. 16B shows a schematic sectional view through the component according to FIG. 16A along the sectional line AA.

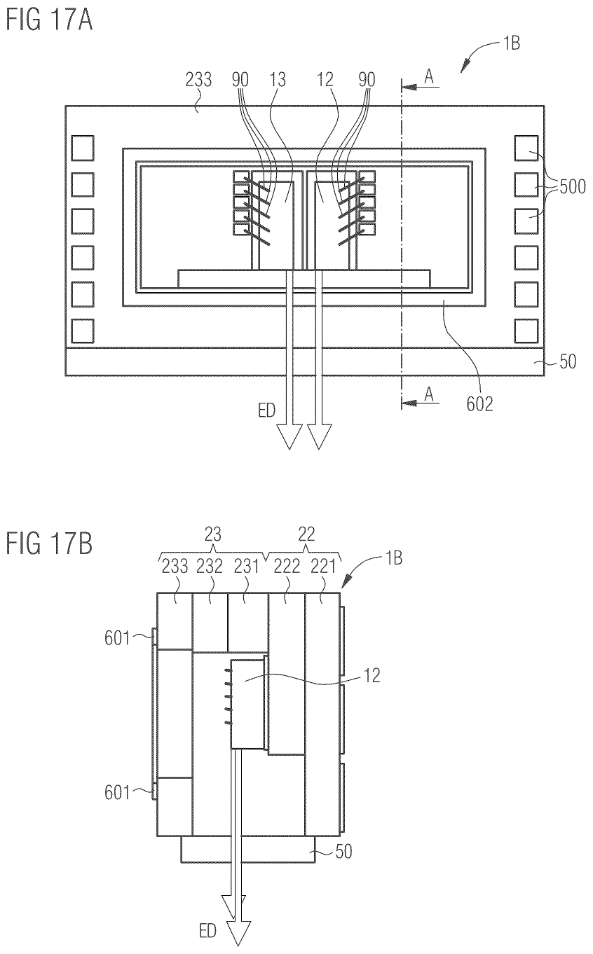

FIG. 17A shows a schematic top view of a second sub-module 1B of an optoelectronic module 1 described herein in a further step of a method for producing a second sub-module 1B. A second semiconductor component 12 and a third semiconductor component 13 are arranged on the mounting side 22A of the second carrier 22. The second and third semiconductor components 12, 13 are mounted through the opening in the third layer 233 of the frame member 23. The second and third semiconductor components 12, 13 each comprise an anode and a cathode for electrical connection. The second and third semiconductor components 12, 13 are each arranged with their cathode on the mounting side 22A of the second carrier 22. Consequently, the second and third semiconductor components 12, 13 are contacted on the cathode side of the second carrier 22. The anodes of the second and third semiconductor components 12, 13 are each located on a side of the second and third semiconductor components 12, 13 opposite the cathode. The anodes of the second and third semiconductor components 12, 13 are each electrically contacted with bond wires 90.

FIG. 17B shows a schematic sectional view through the component according to FIG. 17A along the sectional line AA. In the sectional view, it can be seen that the emission directions ED of the second and third semiconductor components 12, 13 are oriented parallel to a main extension plane of the second carrier 22.

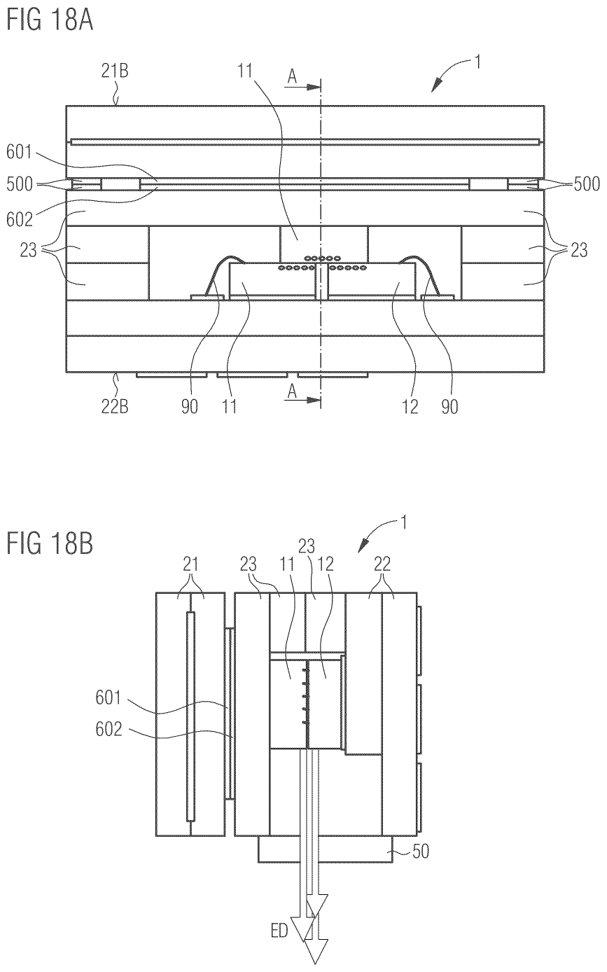

FIGS. 18A and 18B schematic sectional views of an optoelectronic module described herein according to a seventh exemplary embodiment. A first sub-module 1A and a second sub-module 1B are combined with each other to form an optoelectronic module 1. The first sub-module 1A is attached by its first frame element 601 to the second frame element 602 of the second sub-module 1B. For example, the first frame element 601 is connected to the second frame element 602 by soldering. Further, when the first sub-module 1A and the second sub-module 1B are connected, an electrical connection is established between the contact areas 500 on the first sub-module 1A and the contact areas 500 on the second sub-module 1B.

The first sub-module 1A is connected to the second sub-module 1B in such a way that a hermetically sealed optoelectronic module 1 is formed, in which the semiconductor components 11, 12, 13 are protected from external environmental influences. In other words, the semiconductor components 11, 12, 13 are enclosed in the optoelectronic module 1 in a gas-tight and liquid-tight manner.

FIG. 18B shows a schematic sectional view through the component according to FIG. 18A along the sectional line AA. In the sectional view, it is clearly recognizable that an emission of electromagnetic radiation in the emission direction ED takes place through the optical element 50.

The invention is not limited by the description based on the embodiments. Rather, the invention includes any new feature as well as any combination of features, which includes in particular any combination of features in the patent claims, even if this feature or combination itself is not explicitly stated in the patent claims or embodiments.

1. An optoelectronic module comprising:
a first semiconductor component on a mounting side of a first carrier,
a second semiconductor component and a third semiconductor component on a mounting side of a second carrier, wherein
the semiconductor components are configured to emit electromagnetic radiation of different main wavelengths in a common emission direction,
the mounting side of the first carrier faces the mounting side of the second carrier, p1 the semiconductor components comprise a plurality of emitter regions, and
the emitter regions of each semiconductor component can be controlled independently of each other.

2. The optoelectronic module according to claim 1, wherein a frame body is arranged between the first carrier and the second carrier.

3. The optoelectronic module according to claim 2, wherein the frame body is formed with an electrically insulating material and comprises a plurality of electrical connection lines.

4. The optoelectronic module according to claim 3, wherein the connection lines are arranged on an inner side of the frame body.

5. The optoelectronic module according to claim 3, wherein the connection lines are at least partially embedded in the frame body.

6. The optoelectronic module according to claim 2, wherein a connecting material is arranged between the frame body and the first carrier and between the frame body and the second carrier, respectively.

7. The optoelectronic module according to claim 1, wherein the first carrier comprises vias up to an upper side opposite the first semiconductor component.

8. The optoelectronic module according to claim 7, wherein the upper side of the first carrier is electrically conductively connected to the first carrier via bond wires.

9. The optoelectronic module according to claim 8, in which at least two bond wires are associated with each via.

10. The optoelectronic module according to claim 1, wherein the emitter regions of all semiconductor components are arranged facing each other.

11. The optoelectronic module according to claim 1, wherein a distance of the emitter regions of a semiconductor component from each other is at most 10 μm.

12. The optoelectronic module according to claim 1, wherein a lateral distance from the second semiconductor component to the third semiconductor component is at most 30 μm, preferably at most 10 μm.

13. The optoelectronic module according to claim 1, wherein the first semiconductor component is spaced vertically at most 50 μm, preferably at most 30 μm, from the second semiconductor component and the third semiconductor component.

14. The optoelectronic module according to claim 1, wherein the first carrier and/or the second carrier are formed with an electrically insulating material.

15. The optoelectronic module according to claim 1, wherein the second carrier comprises vias to a contact side opposite to the mounting side.

16. A method for producing an optoelectronic module comprising:
providing a first sub-module with a first carrier and a first frame element,
mounting a first semiconductor component on the first carrier,
providing a second sub-module with a second carrier, a frame body and a second frame element,
mounting a second semiconductor component and a third semiconductor component on the second carrier, and
connecting the first sub-module to the second sub-module.

17. The method for producing an optoelectronic module according to claim 16, wherein a plurality of connection lines is introduced into the frame body.

18. The method for producing an optoelectronic module according to claim 16, wherein the first frame element is applied to the second frame element between the first sub-module and the second sub-module.

19. The method for producing an optoelectronic module according to claim 16, wherein the first semiconductor component is mounted on the cathode side and on the anode side on the first carrier.

20. The method for producing an optoelectronic module according to claim 16, wherein, the second semiconductor component and the third semiconductor component are each mounted on the cathode side of the second carrier.
